(19) United States
(12) Patent Application Publication
(10) Pub. No.: US 2026/0353703 A1
(43) Pub. Date: Nov. 5, 2026

(54) SEMICONDUCTOR DEVICE

(71) Applicant: Renesas Electronics Corporation, Tokyo (JP)

(72) Inventor: Atsushi SAKAI, Tokyo (JP)

(21) Appl. No.: 19/462,516

(22) Filed: Jan. 28, 2026

(30) Foreign Application Priority Data
Mar. 18, 2025 (JP) 2025-043858

(51) Int. Cl. H10D 30/65; H10D 30/01; H10D 64/00

(52) U.S. Cl. CPC H10D 30/65; H10D 30/0281; H10D 64/112

(57) ABSTRACT

A semiconductor device of this disclosure includes a semiconductor substrate having an upper surface, a source layer formed at the upper surface and in the semiconductor substrate, a drain layer formed at the upper surface and in the semiconductor substrate, a body layer formed at the upper surface and in the semiconductor substrate, a drift layer formed at the upper surface and in the semiconductor substrate, a first field plate, a second field plate, a first insulating film and a second insulating film. The source layer and the drain layer are arranged with a space between the source layer and the drain layer in a second direction parallel to the upper surface. The body layer surrounds the source layer.

### CROSS-REFERENCE TO RELATED APPLICATIONS

The disclosure of Japanese Patent Application No. 2025-043858 filed on Mar. 18, 2025, including the specification, drawings and abstract is incorporated herein by reference in its entirety.

### BACKGROUND

This disclosure relates to a semiconductor device.

There are disclosed techniques listed below.
[Patent Document 1] Japanese Unexamined Patent Application Publication No. 2018-85373

Patent Document 1 discloses a semiconductor device having a semiconductor substrate. The semiconductor substrate has a source layer, a drain layer, a body layer, and a drift layer formed at the upper surface and in the semiconductor substrate. In cross-sectional view, the source layer and the drain layer are arranged with a space between the source layer and the drain layer. In cross-sectional view, the body layer surrounds the source layer. In cross-sectional view, the drift layer surrounds the drain layer and is in contact with the body layer.

A trench is formed at the upper surface of the semiconductor substrate and is located between the drain layer and the body layer in a direction in which the source layer and the drain layer are arranged. Patent Document 1 further discloses a semiconductor device including an insulating film, a gate insulating film, and a gate electrode. The insulating film is formed in the trench. The gate insulating film is formed on the upper surface of the semiconductor substrate located between the trench and the source layer. The gate electrode GE is formed on the gate insulating film GI. The gate electrode is also formed on the insulating film.

The source layer, the drain layer, the body layer, the drift layer, the gate insulating film, and the gate electrode configure an LDMOS (Laterally Diffused Metal Oxide Semiconductor) transistor. The portion of the gate electrode located on the insulating film functions as a field plate because the portion faces the drift layer with the insulating film interposed.

### SUMMARY

In the semiconductor device disclosed in Patent Document 1, as the thickness of the insulating film increases, the breakdown voltage of the LDMOS transistor improves. On the other hand, as the thickness of the insulating film increases, it becomes difficult for carriers to accumulate in the drift layer facing the field plate with the insulating film interposed when the LDMOS transistor is turned on, i.e., when voltage is applied to the gate electrode, resulting in a decrease in the on-resistance of the LDMOS transistor. Other problems and novel features will become apparent from the description herein and from the accompanying drawings.

The semiconductor device of this disclosure includes a semiconductor substrate having an upper surface, a source layer formed at the upper surface and in the semiconductor substrate, a drain layer formed at the upper surface and in the semiconductor substrate, a body layer formed at the upper surface and in the semiconductor substrate, a drift layer formed at the upper surface and in the semiconductor substrate, a first field plate and a second field plate, and a first insulating film and a second insulating film. The source layer and the drain layer are arranged with a space between the source layer and the drain layer in a second direction parallel to the upper surface. The body layer surrounds the source layer. The drift layer surrounds the drain layer and is in contact with the body layer. The first field plate is located on the drift layer with the first insulating film interposed between the first field plate and the drift layer. The second field plate has a first portion and a second portion. The first portion is located between the first field plate and the drain layer in the second direction and is located on the drift layer with the first insulating film and the second insulating film interposed between the first portion and the drain layer. The second portion is located on the first field plate with the second insulating film interposed between the second portion and the first field plate. A thickness of the first insulating film and a thickness the second insulating film located between the first portion and the drift layer is greater than the thickness of the first insulating film located between the first field plate and the drift layer.

According to the semiconductor device of this disclosure, the trade-off relationship between the breakdown voltage and the on-resistance in the LDMOS transistor can be improved.

### BRIEF DESCRIPTION OF THE DRAWINGS

FIG. 1 is an enlarged plan view of a semiconductor device DEV1.

FIG. 2 is a cross-sectional view of the semiconductor device DEV1 along II-II in FIG. 1.

FIG. 3 is a manufacturing step diagram of the semiconductor device DEV1.

FIG. 4 is a cross-sectional view illustrating the ion implantation step S2 in a manufacturing method of the semiconductor device DEV1.

FIG. 5 is a cross-sectional view illustrating the insulating film formation step S3 in the manufacturing method of the semiconductor device DEV1.

FIG. 6 is a cross-sectional view illustrating the gate insulating film formation step S4 in the manufacturing method of the semiconductor device DEV1.

FIG. 7 is a cross-sectional view illustrating the gate electrode formation step S5 in the manufacturing method of the semiconductor device DEV1.

FIG. 8 is a cross-sectional view illustrating the ion implantation step S6 in the manufacturing method of the semiconductor device DEV1.

FIG. 9 is a cross-sectional view illustrating the sidewall spacer formation step S7 in the manufacturing method of the semiconductor device DEV1.

FIG. 10 is a cross-sectional view illustrating the ion implantation step S8 in the manufacturing method of the semiconductor device DEV1.

FIG. 11 is a cross-sectional view illustrating the insulating film formation step S9 in the manufacturing method of the semiconductor device DEV1.

FIG. 12 is a cross-sectional view illustrating the field plate formation step S10 in the manufacturing method of the semiconductor device DEV1.

FIG. 13 is a cross-sectional view illustrating the interlayer insulating film formation step S11 in the manufacturing method of the semiconductor device DEV1.

FIG. 14 is a cross-sectional view of a semiconductor device DEV4a.

FIG. 15 is a cross-sectional view of a semiconductor device DEV4b.

FIG. 16 is a cross-sectional view of a semiconductor device DEV1a.

FIG. 17 is a cross-sectional view of a semiconductor device DEV2.

FIG. 18 is a cross-sectional view of a semiconductor device DEV3.

FIG. 19 is a manufacturing step diagram of the semiconductor device DEV3.

FIG. 20 is a cross-sectional view illustrating the insulating film formation step S13 in the manufacturing method of the semiconductor device DEV3.

### DETAILED DESCRIPTION

The details of the embodiments of this disclosure will be described with reference to the drawings. In the following drawings, the same reference numerals are used for the same or corresponding parts, and redundant descriptions are not repeated.

### First Embodiment

The semiconductor device DEV1 according to the first embodiment will be described.

### Structure of Semiconductor Device DEV1

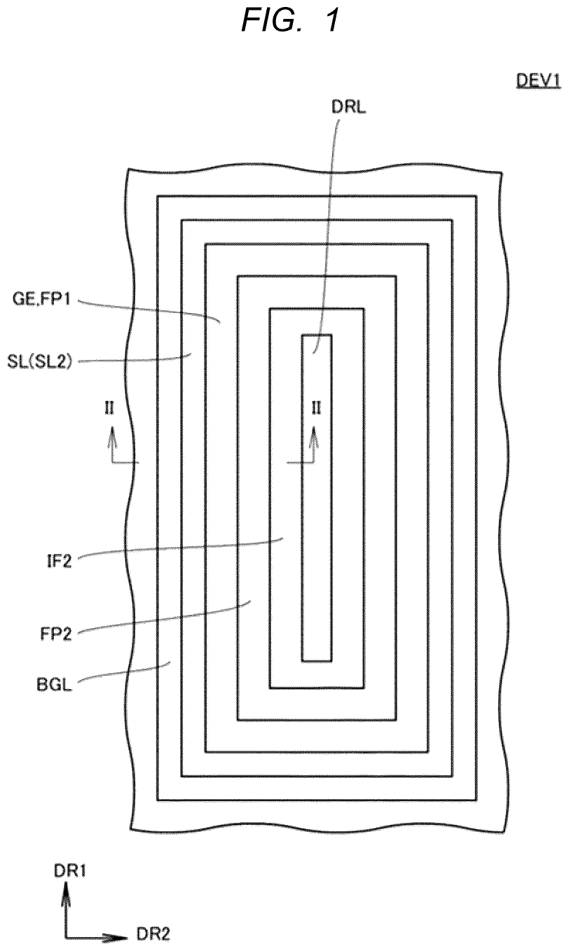

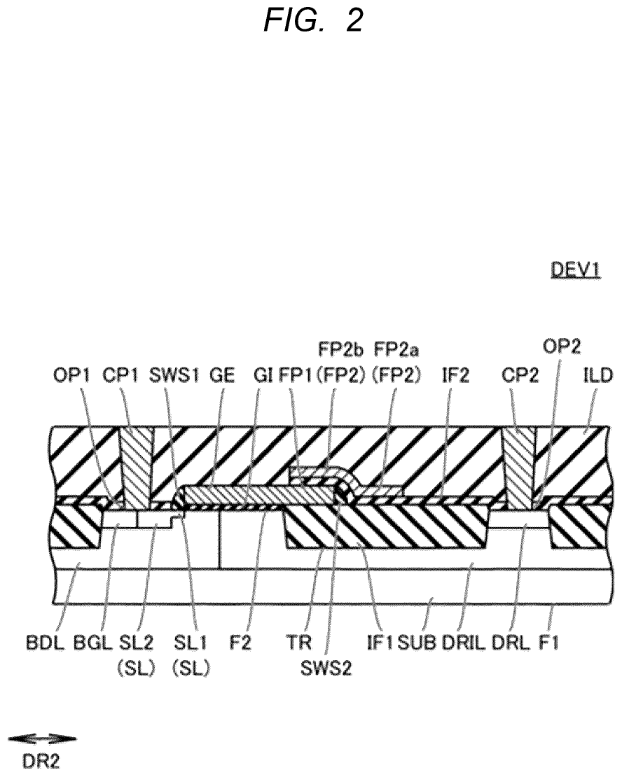

As shown in FIGS. 1 and 2, the semiconductor device DEV1 has a semiconductor substrate SUB. The semiconductor substrate SUB has a lower surface F1 and an upper surface F2 located on the opposite side of the lower surface F1. The semiconductor substrate SUB is formed of, for example, single-crystal silicon. The semiconductor substrate SUB has a source layer SL, a drain layer DRL, a back gate layer BGL, a body layer BDL, and a drift layer DRIL in the semiconductor substrate SUB.

The source layer SL and the drain layer DRL are formed at the upper surface F2 and in the semiconductor substrate SUB. In a cross-sectional view perpendicular to the first direction DR1 parallel to the upper surface F2, the source layer SL and the drain layer DRL are arranged with a space between the source layer SL and the drain layer DRL in the second direction DR2 perpendicular to the first direction DR1. The second direction DR2 is also a direction parallel to the upper surface F2. The source layer SL has a first portion SL1 and a second portion SL2. The first portion SL1 is located between the second portion SL2 and the drain layer DRL in the second direction DR2. The dopant concentration in the first portion SL1 is lower than the dopant concentration in the second portion SL2. That is, the source layer SL has an LDD (Lightly Doped Diffusion) structure.

The back gate layer BGL is formed at the upper surface F2 and in the semiconductor substrate SUB. The back gate layer BGL is located adjacent to the source layer SL. The source layer SL is located between the back gate layer BGL and the drain layer DRL. The body layer BDL is formed at the upper surface F2 and in the semiconductor substrate SUB. In a cross-sectional view perpendicular to the first direction DR1, the body layer BDL surrounds the source layer SL and the back gate layer BGL. The drift layer DRIL is formed at the upper surface F2 and in the semiconductor substrate SUB. In a cross-sectional view perpendicular to the first direction DR1, the drift layer DRIL surrounds the drain layer DRL and is in contact with the body layer BDL.

The conductivity types of the source layer SL, the drain layer DRL, and the drift layer DRIL are the first conductivity type. The conductivity types of the back gate layer BGL and the body layer BDL are the second conductivity type, which is opposite to the first conductivity type. That is, if the first conductivity type is n-type, the second conductivity type is p-type, and if the first conductivity type is p-type, the second conductivity type is n-type.

As shown in FIGS. 1 and 2, the semiconductor device DEV1 further includes an insulating film IF1. A trench TR is formed at the upper surface F2 located between the body layer BDL and the drain layer DRL in the second direction DR2. The trench TR extends toward the lower surface F1. The insulating film IF1 is formed in the trench TR. The insulating film IF1 is formed of, for example, silicon oxide.

As shown in FIGS. 1 and 2, the semiconductor device DEV1 further includes a gate insulating film GI. The gate insulating film GI is formed on the upper surface F2 located between the trench TR and the source layer SL. The gate insulating film GI is formed of, for example, silicon oxide.

As shown in FIGS. 1 and 2, the semiconductor device DEV1 further includes a gate electrode GE and a field plate FP1. The gate electrode GE is formed on the gate insulating film GI. The source layer SL, the drain layer DRL, the body layer BDL, the drift layer DRIL, the gate electrode GE, and the gate insulating film GI configure an LDMOS transistor. The field plate FP1 is formed on the insulating film IF1. From another perspective, the field plate FP1 is located on the drift layer DRIL with the insulating film IF1 interposed between the drift layer DRIL and the field plate FP1. The gate electrode GE and the field plate FP1 are connected to each other. The gate electrode GE and the field plate FP1 are formed of, for example, polycrystalline silicon.

As shown in FIGS. 1 and 2, the semiconductor device DEV1 further includes a sidewall spacer SWS1 and a sidewall spacer SWS2. The sidewall spacer SWS1 is formed on the first portion SL1 of the source layer SL so as to be in contact with the side surface of the gate electrode GE. The sidewall spacer SWS2 is formed on the insulating film IF1 so as to be in contact with the side surface of the field plate FP1. The sidewall spacer SWS1 and the sidewall spacer SWS2 are formed of, for example, silicon nitride.

As shown in FIGS. 1 and 2, the semiconductor device DEV1 further includes an insulating film IF2. The insulating film IF2 is formed on the upper surface F2, on the sidewall spacer SWS2, on the insulating film IF1, and on the field plate FP1. An opening OP1 and an opening OP2 are formed in the insulating film IF2. The source layer SL and the back gate layer BGL are exposed from the opening OP1, and the drain layer DRL is exposed from the opening OP2. The insulating film IF2 is formed of, for example, silicon oxide.

As shown in FIGS. 1 and 2, the semiconductor device DEV1 further includes a field plate FP2. The field plate FP2 has a first portion FP2a and a second portion FP2b in the second direction DR2. The first portion FP2a is formed on the insulating film IF2 so as to be located between the field plate FP1 and the drain layer DRL in the second direction DR2. From another perspective, the first portion FP2a is located on the drift layer DRIL with the insulating film IF1 and the insulating film IF2 interposed between the first portion FP2a and the drift layer DRIL. Therefore, the thickness of the insulating films (insulating films IF1 and IF2) located between the first portion FP2a and the drift layer DRIL is greater than the thickness of the insulating film (insulating film IF1) located between the field plate FP1 and the drift layer DRIL. The second portion FP2b is formed on the field plate FP1 with the insulating film IF2 interposed between the second portion FP2b and the field plate FP1. The field plate FP2 is formed of a metal material such as titanium nitride.

As shown in FIG. 2, the semiconductor device DEV1 further includes an interlayer insulating film ILD, a contact plug CP1 and a contact plug CP2. The interlayer insulating film ILD is formed on the field plate FP2, on the gate electrode GE, on the sidewall spacer SWS1, and on the insulating film IF2. The contact plug CP1 and the contact plug CP2 are formed in the interlayer insulating film ILD. The lower end of the contact plug CP1 is connected to the source layer SL and the back gate layer BGL, and the lower end of the contact plug CP2 is connected to the drain layer DRL. The contact plug CP1 and the contact plug CP2 are formed of, for example, tungsten.

Although not shown, a first wiring, a second wiring, and a third wiring are formed on the interlayer insulating film ILD. The first wiring is electrically connected to the source layer SL and the back gate layer BGL via the contact plug CP1. The second wiring is electrically connected to the drain layer DRL via the contact plug CP2. The third wiring is electrically connected to the gate electrode GE via a contact plug (not shown) formed in the interlayer insulating film ILD. The field plate FP2 is electrically connected to the first wiring or the third wiring via a contact plug (not shown) formed in the interlayer insulating film ILD.

### Manufacturing Method of Semiconductor Device DEV1

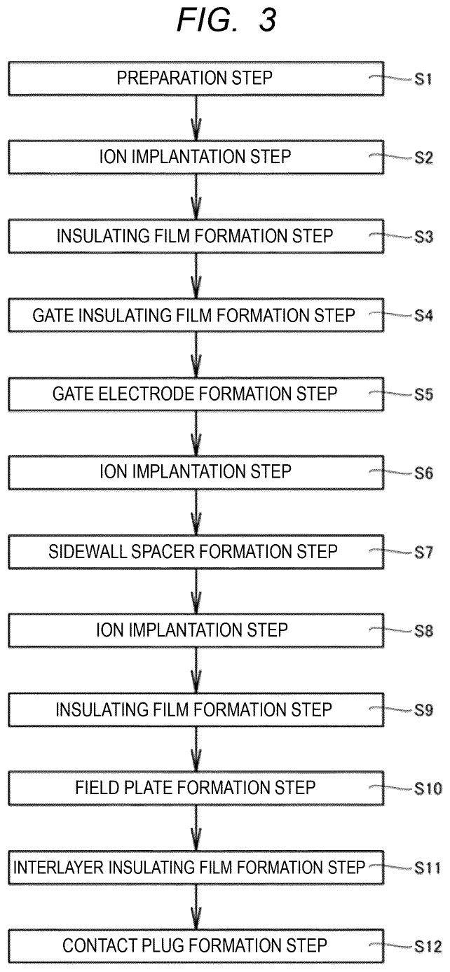

As shown in FIG. 3, the manufacturing method of the semiconductor device DEV1 includes a preparation step S1. In the preparation step S1, a semiconductor substrate SUB is prepared.

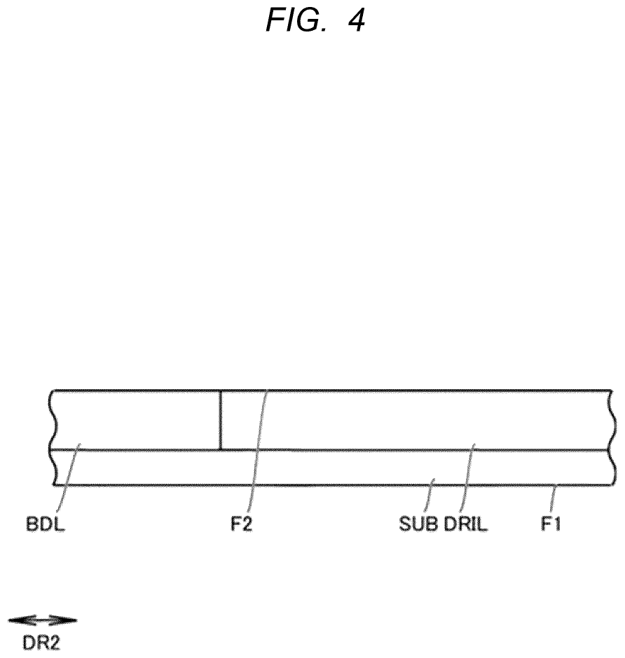

As shown in FIG. 3, the manufacturing method of the semiconductor device DEV1 further includes an ion implantation step S2. The ion implantation step S2 is performed after the preparation step S1. As shown in FIG. 4, in the ion implantation step S2, ion implantation into the semiconductor substrate SUB is performed to form the body layer BDL and the drift layer DRIL.

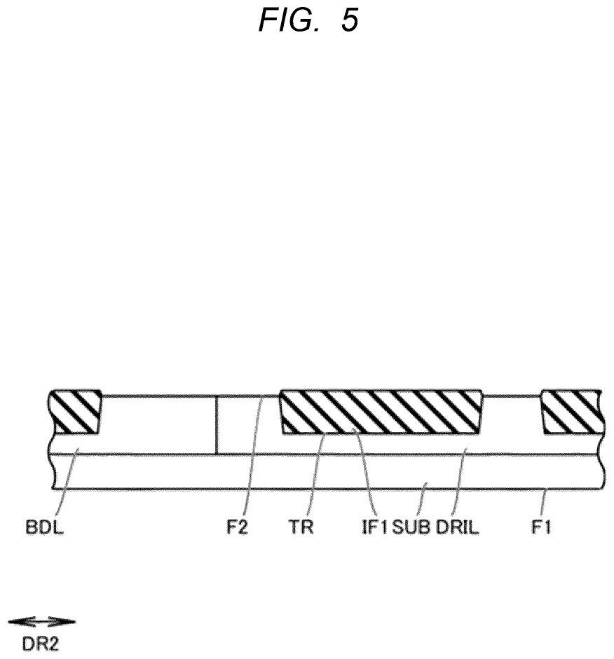

As shown in FIG. 3, the manufacturing method of the semiconductor device DEV1 further includes an insulating film formation step S3. The insulating film formation step S3 is performed after the ion implantation step S2. As shown in FIG. 5, in the insulating film formation step S3, a trench TR is formed at the upper surface F2. In the insulating film formation step S3, an insulating film IF1 is formed in the trench TR. In the insulating film formation step S3, first, a hard mask is formed on the upper surface F2. The hard mask includes, for example, a silicon oxide film and a silicon nitride film formed on the silicon oxide film. Second, a resist pattern having an opening is formed on the hard mask. The resist pattern is formed by exposing and developing a photoresist applied on the hard mask using photolithography. Third, an opening is formed in the hard mask by performing dry etching on the hard mask through the opening of the resist pattern. Fourth, the trench TR is formed by performing dry etching on the semiconductor substrate SUB through the opening of the hard mask.

Fifth, the constituent material of the insulating film IF1 is formed in the trench TR and on the hard mask by, for example, a CVD (Chemical Vapor Deposition) method. Sixth, the constituent material of the insulating film IF1 formed outside the trench TR is removed by, for example, a CMP (Chemical Mechanical Polishing) method or etch-back. In this way, the trench TR and the insulating film IF1 are formed.

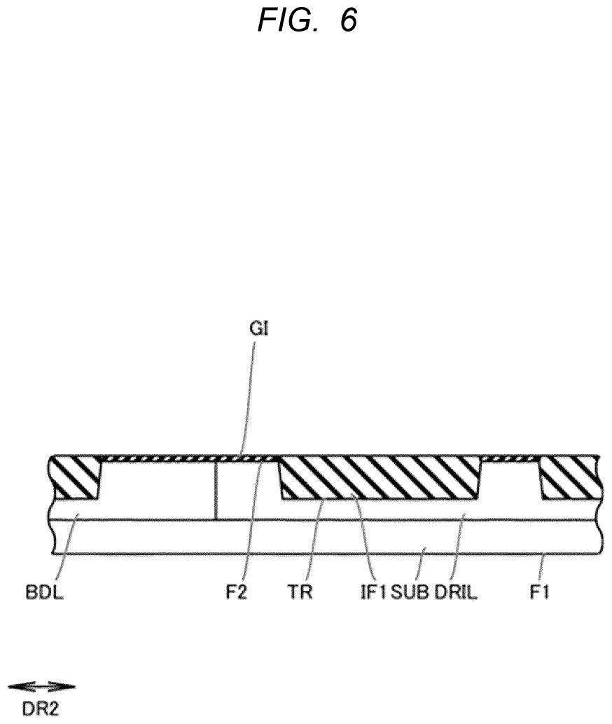

As shown in FIG. 3, the manufacturing method of the semiconductor device DEV1 further includes a gate insulating film formation step S4. The gate insulating film formation step S4 is performed after the insulating film formation step S3. As shown in FIG. 6, in the gate insulating film formation step S4, a gate insulating film GI is formed on the upper surface F2 by, for example, thermal oxidation of the semiconductor substrate SUB.

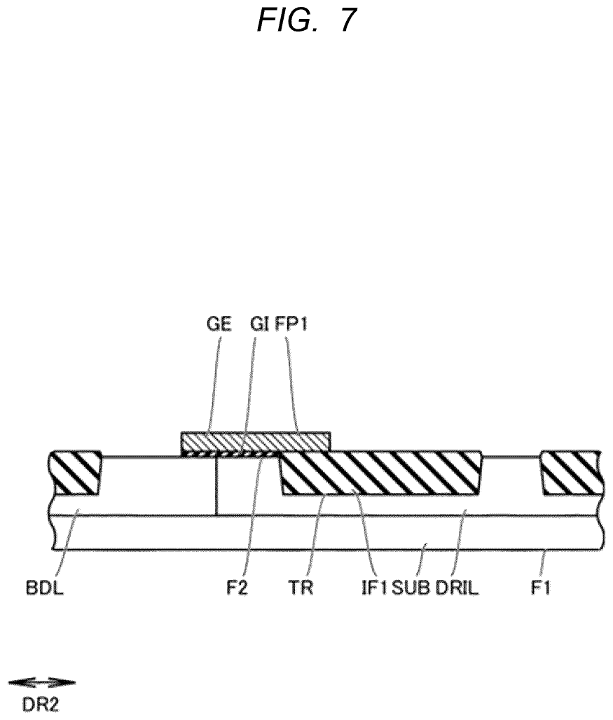

As shown in FIG. 3, the manufacturing method of the semiconductor device DEV1 further includes a gate electrode formation step S5. The gate electrode formation step S5 is performed after the gate insulating film formation step S4. As shown in FIG. 7, in the gate electrode formation step S5, a gate electrode GE is formed on the gate insulating film GI. In the gate electrode formation step S5, the field plate FP1 is formed on the insulating film IF1.

In the gate electrode formation step S5, first, the constituent material of the gate electrode GE and the like is formed on the gate insulating film GI and the insulating film IF1 by, for example, a CVD method. Second, a resist pattern having an opening is formed on the constituent material of the gate electrode GE and the like. Third, dry etching is performed on the constituent material of the gate electrode GE and the like through the opening of the resist pattern. Thus, the gate electrode GE and the field plate FP1 are formed.

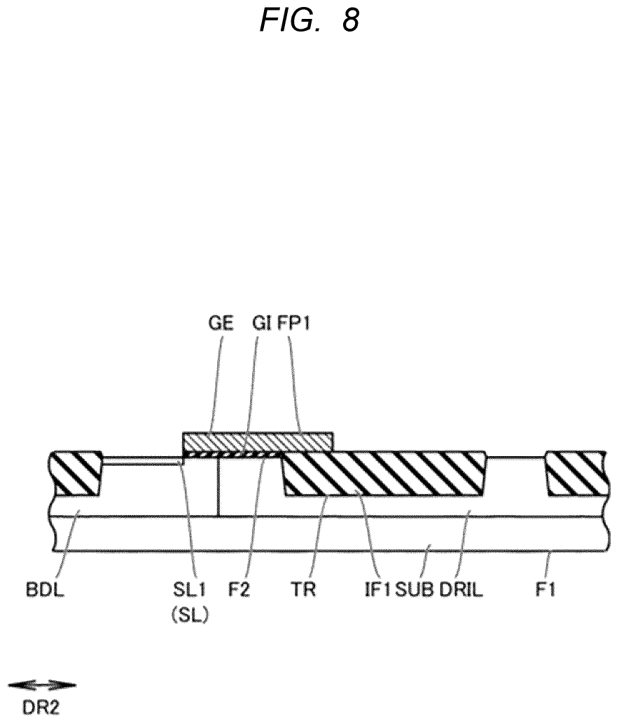

As shown in FIG. 3, the manufacturing method of the semiconductor device DEV1 further includes an ion implantation step S6. The ion implantation step S6 is performed after the gate electrode formation step S5. As shown in FIG. 8, in the ion implantation step S6, ion implantation into the semiconductor substrate SUB is performed to form the first portion SL1 of the source layer SL.

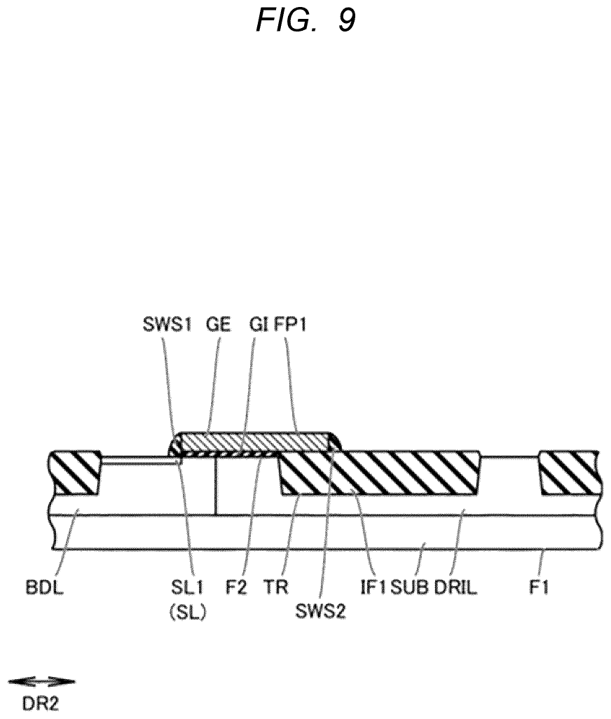

As shown in FIG. 3, the manufacturing method of the semiconductor device DEV1 further includes a sidewall spacer formation step S7. The sidewall spacer formation step S7 is performed after the ion implantation step S6. As shown in FIG. 9, in the sidewall spacer formation step S7, the sidewall spacer SWS1 is formed on the first portion SL1 of the source layer SL so as to be in contact with the side surface of the gate electrode GE. In the sidewall spacer formation step S7, the sidewall spacer SWS2 is formed on the insulating film IF1 so as to be in contact with the side surface of the field plate FP1. In the sidewall spacer formation step S7, first, the constituent material of the sidewall spacer SWS1 and the like is formed on the upper surface F2 so as to cover the gate electrode GE, the field plate FP1, and the insulating film IF1 by, for example, a CVD method. Second, etch-back is performed on the constituent material of the sidewall spacer SWS1 and the like. Thus, the sidewall spacer SWS1 and the sidewall spacer SWS2 are formed.

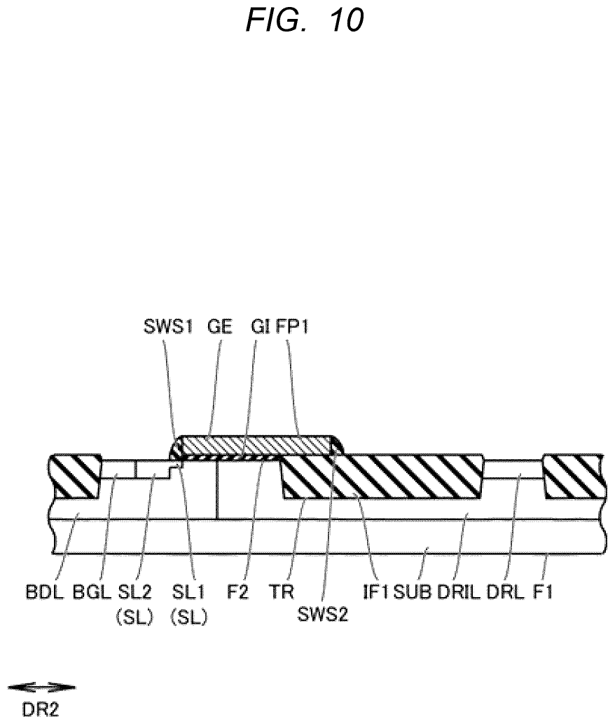

As shown in FIG. 3, the manufacturing method of the semiconductor device DEV1 further includes an ion implantation step S8. The ion implantation step S8 is performed after the sidewall spacer formation step S7. As shown in FIG. 10, in the ion implantation step S8, ion implantation into the semiconductor substrate SUB is performed to form the second portion SL2 of the source layer SL, the drain layer DRL, and the back gate layer BGL.

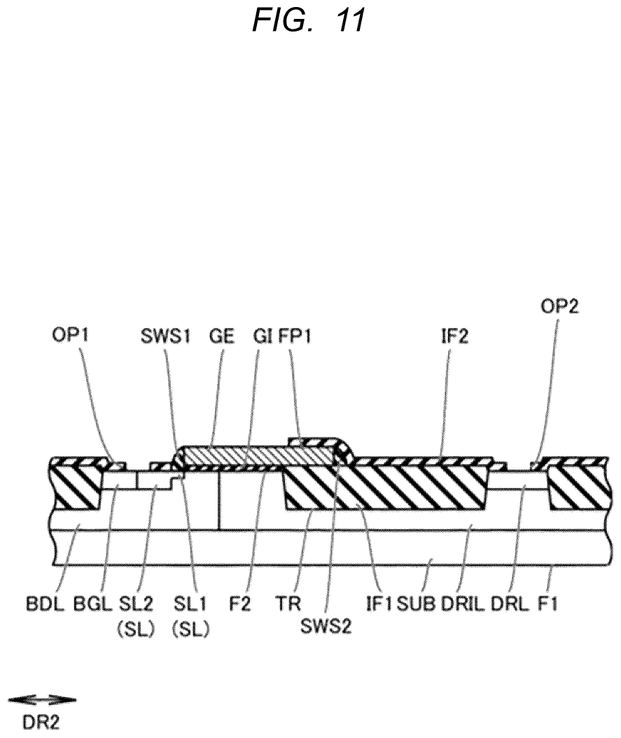

As shown in FIG. 3, the manufacturing method of the semiconductor device DEV1 further includes an insulating film formation step S9. The insulating film formation step S9 is performed after the ion implantation step S8. As shown in FIG. 11, in the insulating film formation step S9, the insulating film IF2 is formed on the upper surface F2 so as to cover the field plate FP1, the sidewall spacer SWS2, and the insulating film IF1.

In the insulating film formation step S9, first, for example by the CVD method, the material of the insulating film IF2 is formed on the upper surface F2 so as to cover the gate electrode GE, the field plate FP1, the sidewall spacer SWS1, the sidewall spacer SWS2, and the insulating film IF1. Second, a resist pattern having openings is formed on the material of the insulating film IF2. Third, patterning of the insulating film IF2 is performed by dry etching the material of the insulating film IF2 through the openings of the resist pattern, and an opening OP1 and an opening OP2 are also formed. Thus, the insulating film IF2 is formed.

Although not shown, after the insulating film formation step S9 is performed, silicidation is carried out on the upper surface F2 exposed from the opening OP1 and the opening OP2. At this time, silicidation is also performed on the upper surface of the gate electrode GE. That is, the insulating film IF2 functions as a silicide blocking film.

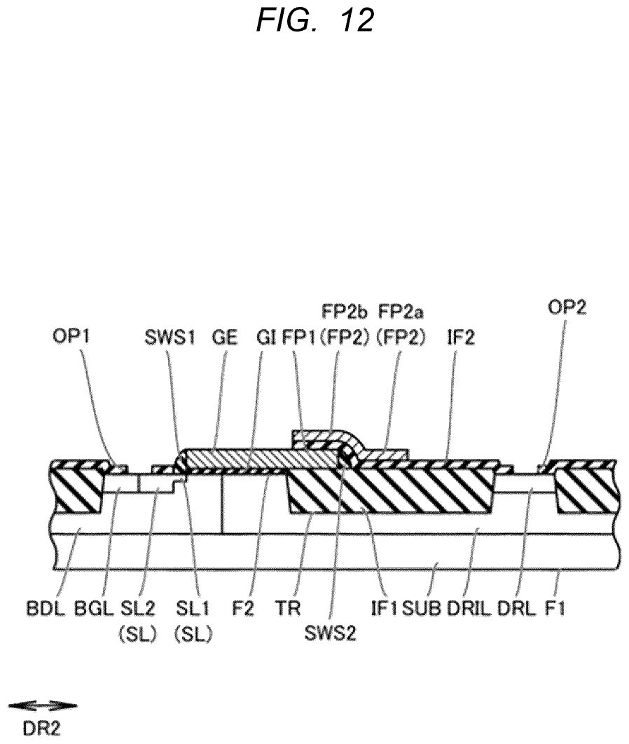

As shown in FIG. 3, the manufacturing method of the semiconductor device DEV1 further includes a field plate formation step S10. As shown in FIG. 12, in the field plate formation step S10, the field plate FP2 is formed on the insulating film IF2. In the field plate formation step S10, first, for example by the sputtering method, the material of the field plate FP2 is formed on the insulating film IF2 so as to cover the gate electrode GE and the sidewall spacer SWS1. Second, a resist pattern having openings is formed on the material of the field plate FP2. Third, dry etching is performed on the material of the field plate FP2 through the openings of the resist pattern. Thus, the field plate FP2 is formed.

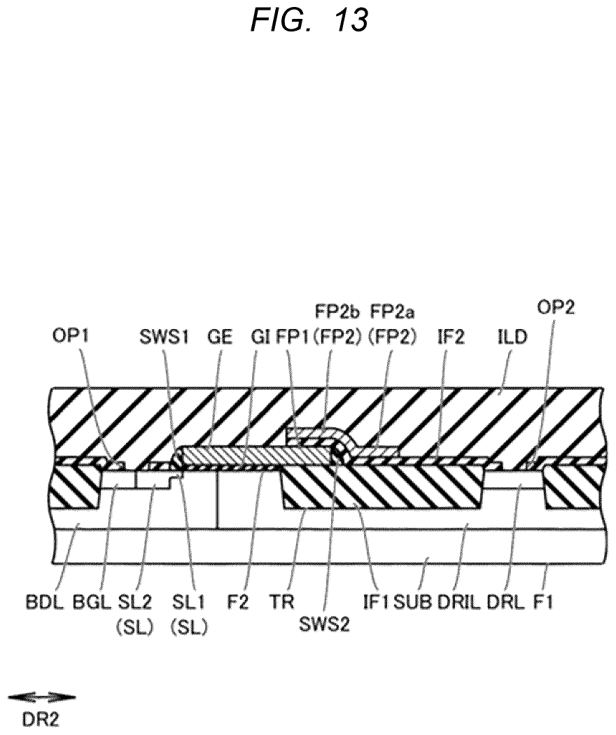

As shown in FIG. 3, the manufacturing method of the semiconductor device DEV1 further includes an interlayer insulating film formation step S11. The interlayer insulating film formation step S11 is performed after the field plate formation step S10. As shown in FIG. 13, in the interlayer insulating film formation step S11, the interlayer insulating film ILD is formed on the gate electrode GE, on the sidewall spacer SWS1, on the insulating film IF2, and on the field plate FP2. In the interlayer insulating film formation step S11, first, for example by the CVD method, the material of the interlayer insulating film ILD is formed on the gate electrode GE, on the sidewall spacer SWS1, on the insulating film IF2, and on the field plate FP2. Second, the upper surface of the material of the interlayer insulating film ILD is planarized, for example, by the CMP method. Thus, the interlayer insulating film ILD is formed.

As shown in FIG. 3, the manufacturing method of the semiconductor device DEV1 further includes a contact plug formation step S12. The contact plug formation step S12 is performed after the interlayer insulating film formation step S11. In the contact plug formation step S12, a contact plug CP1 and a contact plug CP2 are formed in the interlayer insulating film ILD. In the contact plug formation step S12, first, a resist pattern having openings is formed on the interlayer insulating film ILD. Second, by performing dry etching on the interlayer insulating film ILD through the openings of the resist pattern, contact holes are formed at positions overlapping the source layer SL and the body layer BDL in plan view. At this time, in the interlayer insulating film ILD, contact holes are also formed at positions overlapping the drain layer DRL in plan view. Third, for example, by the CVD method, the material of contact plugs such as the contact plug CP1 is formed in the contact holes and on the interlayer insulating film ILD. Fourth, for example by the CMP method, the material of contact plugs such as the contact plug CP1 formed outside the contact holes is removed. Thus, the contact plug CP1 and the contact plug CP2 are formed, and the structure of the semiconductor device DEV1 shown in FIGS. 1 and 2 is obtained.

### Effect of Semiconductor Device DEV1

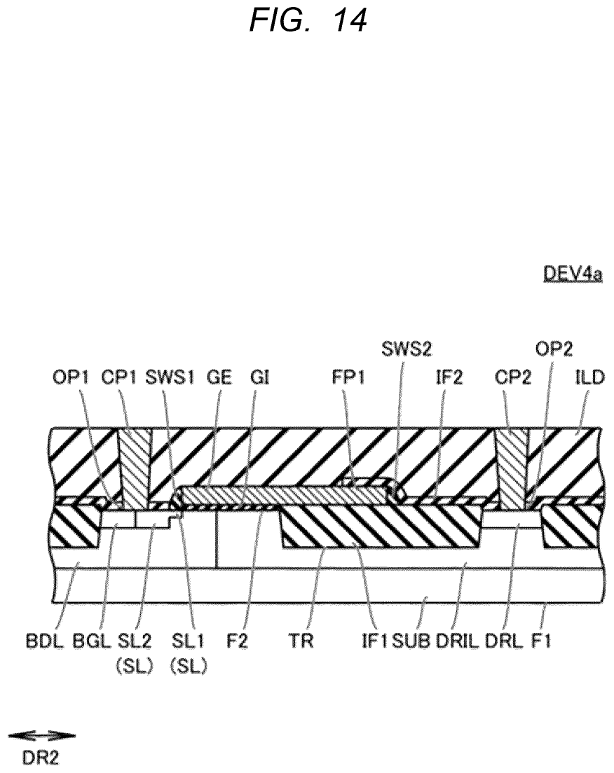

As shown in FIG. 14, the semiconductor device DEV4a according to First comparative example does not have a field plate FP2. In the semiconductor device DEV4a, increasing the thickness of the insulating film IF1 can enhance the breakdown voltage of the LDMOS transistor. However, if the thickness of the insulating film IF1 is increased, when the LDMOS transistor is turned on, that is, when voltage is applied to the gate electrode GE and the field plate FP1, it becomes difficult for carriers to accumulate in the portion of the drift layer DRIL facing the field plate FP1 via the insulating film IF1, resulting in an increase in the on-resistance of the LDMOS transistor. Therefore, in the semiconductor device DEV4a, if an attempt is made to increase the breakdown voltage of the LDMOS transistor, the on-resistance of the LDMOS transistor increases, and if an attempt is made to reduce the on-resistance of the LDMOS transistor, the breakdown voltage of the LDMOS transistor decreases.

In the semiconductor device DEV1, while the insulating film IF1 is interposed between the field plate FP1 and the drift layer DRIL, both the insulating film IF1 and the insulating film IF2 are interposed between the field plate FP2 and the drift layer DRIL. That is, in the semiconductor device DEV1, the thickness of the insulating film located under the field plate at a position where a strong electric field is likely to be applied is greater than the thickness of the insulating film located under the field plate at a position where a strong electric field is less likely to be applied.

Therefore, in the semiconductor device DEV1, there is no need to increase the thickness of the insulating film IF1 located between the field plate FP1 and the drift layer DRIL, so it does not become difficult for carriers to accumulate in the drift layer DRIL facing the field plate FP1 via the insulating film IF1, and the increase in the on-resistance of the LDMOS transistor can be suppressed. Also, in the semiconductor device DEV1, since both the insulating film IF1 and the insulating film IF2 are interposed between the field plate FP2 and the drift layer DRIL, the breakdown voltage of the LDMOS transistor is enhanced. Thus, according to the semiconductor device DEV1, the trade-off relationship between the breakdown voltage and on-resistance in the LDMOS transistor is improved.

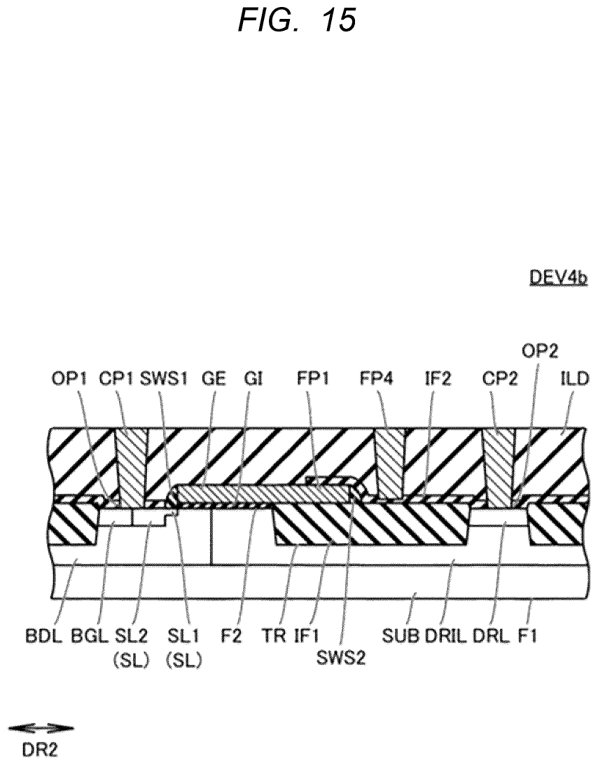

As shown in FIG. 15, the semiconductor device DEV4b according to Second comparative example has a field plate FP4 instead of the field plate FP2. The field plate FP4 is formed in the interlayer insulating film ILD. The field plate FP4 is formed, for example, of tungsten. The field plate FP4 is located between the field plate FP1 and the drain layer DRL in the second direction DR2. The field plate FP4 is electrically connected to the source layer SL by wiring (not shown) formed on the interlayer insulating film ILD.

The field plate FP4 is formed together with the contact plug CP1 and the contact plug CP2 in the contact plug formation step S12. The contact holes are formed by performing dry etching on the interlayer insulating film ILD through the openings of the resist pattern, but at that time, part or all of the insulating film IF2 may be removed. Therefore, if mask misalignment occurs in the contact plug formation step S12, the field plate FP4 is formed so as to overlap the field plate FP1 in plan view, and the field plate FP4 comes into contact with the field plate FP1. To avoid conduction between the source layer SL and the gate electrode GE due to the contact between the field plate FP4 and the field plate FP1, the field plate FP2 needs to be formed so as to be separated from the field plate FP1 in the second direction DR2. As a result, in the semiconductor device DEV4b, insulation breakdown is likely to occur in the areas where the field plate is not formed between the field plate FP1 and the field plate FP4, leading to a decrease in the breakdown voltage of the LDMOS transistor.

In the semiconductor device DEV1, while the first portion FP2a of the field plate FP2 is located between the field plate FP1 and the drain layer DRL in the second direction DR2, the second portion FP2b of the field plate FP2 is located on the field plate FP1 with the insulating film IF2 interposed. Therefore, in the semiconductor device DEV1, there are fewer areas where the field plate is not formed between the first portion FP2a of the field plate FP2 and the field plate FP1. Therefore, according to the semiconductor device DEV1, the breakdown voltage of the LDMOS transistor is enhanced even compared to the semiconductor device DEV4b.

### MODIFIED EXAMPLE

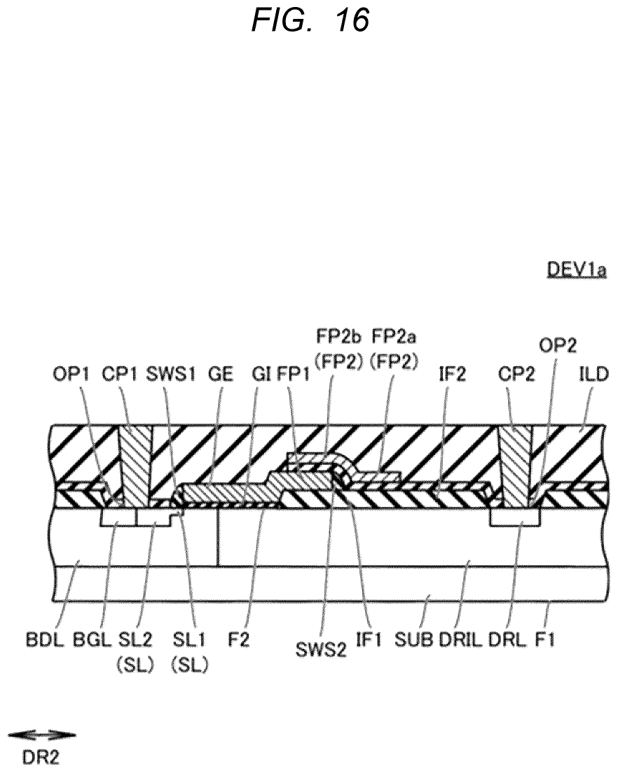

As shown in FIG. 16, in the semiconductor device DEV1a according to a modified example of the semiconductor device DEV1, a trench TR does not need to be formed at the upper surface F2, and the insulating film IF1 may be formed on the upper surface F2. In this case as well, since the thickness of the insulating film located under the field plate at a position where a strong electric field is likely to be applied is greater than the thickness of the insulating film located under the field plate at a position where a strong electric field is less likely to be applied, the trade-off relationship between the breakdown voltage and on-resistance in the LDMOS transistor is similarly improved.

### Second Embodiment

The semiconductor device DEV2 according to the second embodiment will be described. Here, the differences from the semiconductor device DEV1 will be mainly described, and redundant explanations will not be repeated.

### Structure of Semiconductor Device DEV2

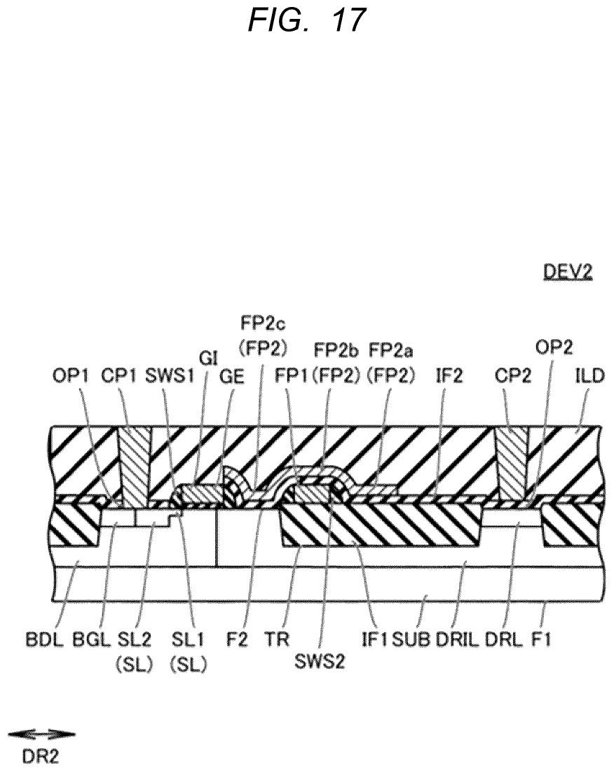

As shown in FIG. 17, in the semiconductor device DEV2, the gate electrode GE and the field plate FP1 are separated from each other in the second direction DR2. In the semiconductor device DEV2, the insulating film IF2 is also formed on the upper surface F2 located between the gate electrode GE and the field plate FP1 (insulating film IF1) in the second direction DR2. In the semiconductor device DEV2, the thickness of the insulating film IF2 is, for example, greater than the thickness of the gate insulating film GI.

In the semiconductor device DEV2, the field plate FP2 further includes a third portion FP2c. The third portion FP2c is formed on the insulating film IF2 located between the gate electrode GE and the field plate FP1 in the second direction DR2. That is, the third portion FP2c is located between the gate electrode GE and the field plate FP1 in the second direction DR2, and is located on the drift layer DRIL with the insulating film IF2 interposed between the third portion FP2c and the drift layer DRIL.

### Effects of Semiconductor Device DEV2

As shown in FIG. 2, in the semiconductor device DEV1, the drift layer DRIL located between the gate electrode GE and the insulating film IF1 in the second direction DR2 faces the gate electrode GE with the gate insulating film GI interposed. Since the thickness of the gate insulating film GI is smaller than the thickness of the insulating film IF1 and the insulating film IF2, the relaxation of the electric field applied to the drift layer DRIL located between the gate electrode GE and the insulating film IF1 may be insufficient.

As shown in FIG. 17, in the semiconductor device DEV2, an insulating film IF2 thicker than the gate insulating film GI is formed on the upper surface F2 located between the gate electrode GE and the insulating film IF1 in the second direction DR2. In the semiconductor device DEV2, a field plate FP2 (third portion FP2c) is formed on the insulating film IF2 located between the gate electrode GE and the insulating film IF1 in the second direction DR2. Therefore, in the semiconductor device DEV2, the insulating film located on the drift layer DRIL between the gate electrode GE and the insulating film IF1 is thicker than that in the semiconductor device DEV1, resulting in improved breakdown voltage of the LDMOS transistor compared to the semiconductor device DEV1.

### Third Embodiment

The semiconductor device DEV3 according to the third embodiment will be described. Here, the differences from the semiconductor device DEV1 will be mainly described, and redundant explanations will not be repeated.

### Structure of Semiconductor Device DEV3

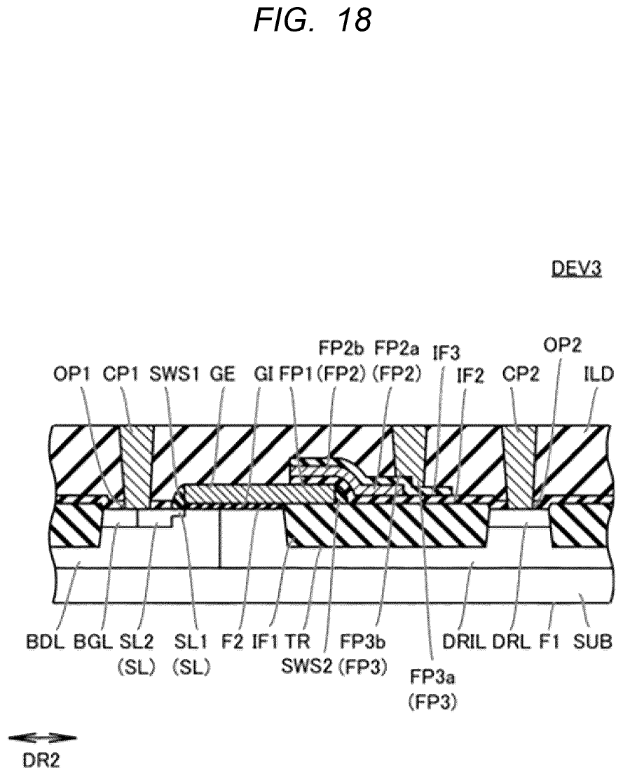

As shown in FIG. 18, the semiconductor device DEV3 further includes an insulating film IF3. The insulating film IF3 is formed on the insulating film IF2. The insulating film IF3 is also formed on the field plate FP2 (first portion FP2a and second portion FP2b). The insulating film IF3 is formed of, for example, silicon oxide.

In the semiconductor device DEV3, the interlayer insulating film ILD is formed on the insulating film IF3, the gate electrode GE, the sidewall spacer SWS1, and the insulating film IF2. The semiconductor device DEV3 further includes a field plate FP3. The field plate FP3 is formed in the interlayer insulating film ILD. The field plate FP3 is formed of, for example, tungsten.

The field plate FP3 includes a fourth portion FP3a and a fifth portion FP3b. The fourth portion FP3a is formed on the insulating film IF3 so as to be located between the first portion FP2a of the field plate FP2 and the drain layer DRL in the second direction DR2. That is, the fourth portion FP3a is located on the drift layer DRIL with the insulating films IF1, IF2, IF3 interposed between the fourth portion FP3a and the drift layer DRIL. The fifth portion FP3b is formed on the first portion FP2a of the field plate FP2 with the insulating film IF3 interposed.

### Manufacturing Method of Semiconductor Device DEV3

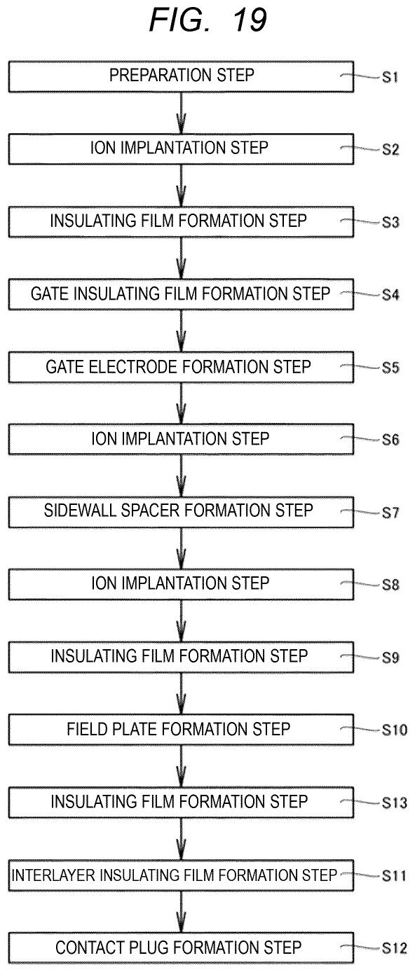

As shown in FIG. 19, the manufacturing method of the semiconductor device DEV3 further includes an insulating film formation step S13. The insulating film formation step S13 is performed after the field plate formation step S10 and before the interlayer insulating film formation step S11.

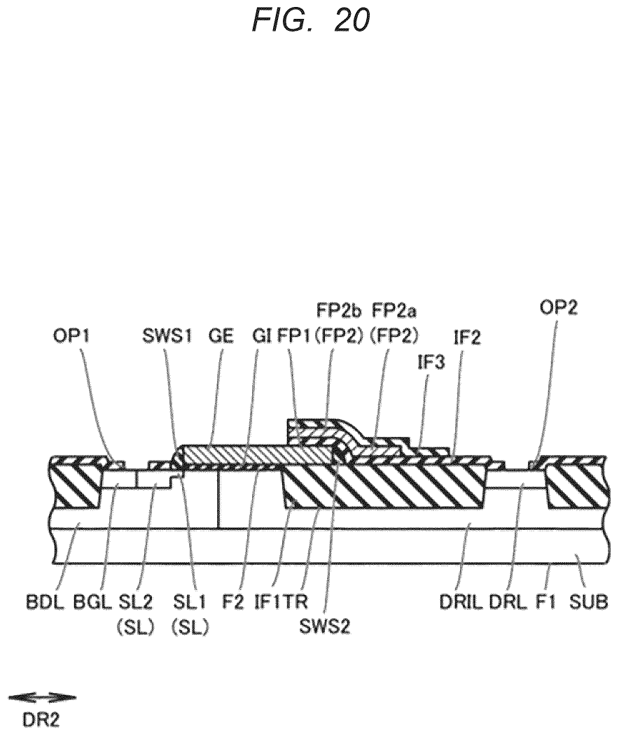

As shown in FIG. 20, in the insulating film formation step S13, the insulating film IF3 is formed on the insulating film IF2 and the field plate FP2. In the insulating film formation step S13, first, for example, by the CVD method, the constituent material of the insulating film IF3 is formed on the field plate FP2, the insulating film IF2, the gate electrode GE, and the sidewall spacer SWS1. Second, a resist pattern having an opening is formed on the constituent material of the insulating film IF3. Third, dry etching is performed on the constituent material of the insulating film IF3 through the opening of the resist pattern. Thus, the insulating film IF3 is formed.

In the manufacturing method of the semiconductor device DEV3, in the contact plug formation step S12, the field plate FP3 is also formed in the same manner as the contact plug CP1 and the contact plug CP2. Thus, the structure of the semiconductor device DEV3 shown in FIG. 18 is obtained.

### Effects of Semiconductor Device DEV3

In the semiconductor device DEV3, the fourth portion FP3a is located between the first portion FP2a of the field plate FP2 and the drain layer DRL in the second direction DR2. In the semiconductor device DEV3, while the insulating film IF1 and the insulating film IF2 are interposed between the first portion FP2a of the field plate FP2 and the drift layer DRIL, the insulating film IF1, the insulating film IF2, and the insulating film IF3 are interposed between the fourth portion FP3a and the drift layer DRIL. Thus, in the semiconductor device DEV3, the thickness of the insulating film located under the field plate at a position where a stronger electric field is likely to be applied is greater.

In the semiconductor device DEV3, the fifth portion FP3b is formed on the first portion FP2a of the field plate FP2 with the insulating film IF3 interposed, reducing the areas where no field plate is formed between the first portion FP2a of the field plate FP2 and the fourth portion FP3a. Therefore, according to the semiconductor device DEV3, the breakdown voltage of the LDMOS transistor can be further increased compared to the semiconductor device DEV1.

Although the invention made by the inventor has been specifically described based on the embodiments, it is needless to say that the present invention is not limited to the above embodiments and various modifications can be made without departing from the gist thereof.

What is claimed is:

1. A semiconductor device comprising:
a semiconductor substrate having an upper surface;
a source layer formed in the semiconductor substrate and at the upper surface;
a drain layer formed in the semiconductor substrate and at the upper surface;
a body layer formed in the semiconductor substrate and at the upper surface;
a drift layer formed in the semiconductor substrate and at the upper surface;
a first field plate and a second field plate; and
a first insulating film and a second insulating film,
wherein the source layer and the drain layer are arranged with a space between the source layer and the drain layer in a second direction parallel to the upper surface,
wherein the body layer surrounds the source layer,
wherein the drift layer surrounds the drain layer and is in contact with the body layer,
wherein the first field plate is located on the drift layer with the first insulating film interposed between the first field plate and the drift layer,
wherein the second field plate includes a first portion and a second portion,
wherein the first portion is located between the first field plate and the drain layer in the second direction, and is located on the drift layer with the first insulating film and the second insulating film interposed between the first portion and the drain layer,
wherein the second portion is located on the first field plate with the second insulating film interposed between the second portion and the first field plate, and
wherein a thickness of the first insulating film and a thickness of the second insulating film located between the first portion and the drift layer is greater than the thickness of the first insulating film located between the first field plate and the drift layer.

2. The semiconductor device according to claim 1,
wherein the semiconductor substrate has a lower surface located on the opposite side of the upper surface,
wherein a trench extending toward the lower surface is formed at the upper surface located between the body layer and the drain layer in the second direction,
wherein the first insulating film is formed in the trench, and
wherein the second insulating film is formed on the first insulating film and on the first field plate.

3. The semiconductor device according to claim 1,
wherein the first insulating film is formed on the upper surface located between the body layer and the drain layer in the second direction, and
wherein the second insulating film is formed on the first insulating film and on the first field plate.

4. The semiconductor device according to claim 1, comprising:
a gate insulating film formed on the upper surface located between the first insulating film and the source layer in the second direction; and
a gate electrode formed on the gate insulating film.

5. The semiconductor device according to claim 4,
wherein the gate electrode is connected to the first field plate.

6. The semiconductor device according to claim 5,
wherein the second field plate is electrically connected to the source layer.

7. The semiconductor device according to claim 5,
wherein the second field plate is electrically connected to the gate electrode.

8. The semiconductor device according to claim 4,
wherein the gate electrode and the first field plate are spaced apart from each other in the second direction.

9. The semiconductor device according to claim 8,
wherein the second insulating film is formed on the first insulating film, on the first field plate, and on the upper surface located between the first field plate and the gate electrode in the second direction,
wherein the thickness of the second insulating film is greater than a thickness of the gate insulating film,
wherein the second field plate includes a third portion, and
wherein the third portion is located between the first field plate and the gate electrode in the second direction, and is located on the drift layer with the second insulating film interposed between the third portion and the drift layer.

10. The semiconductor device according to claim 1, comprising:
a third field plate; and
a third insulating film,
wherein the third field plate includes a fourth portion and a fifth portion,
wherein the fourth portion is located between the first portion and the drain layer in the second direction, and is located on the drift layer with the first insulating film, the second insulating film, and the third insulating film interposed between the fourth portion and the drain layer, and
wherein the fifth portion is located on the first portion with the third insulating film interposed between the fifth portion and the first portion.

11. The semiconductor device according to claim 10, comprising:
an interlayer insulating film formed on the upper surface to cover the first insulating film, the second insulating film, and the third insulating film,
wherein the third field plate is formed in the interlayer insulating film.
